(19) United States
(12) Patent Application Publication
(10) Pub. No.: US 2010/0075506 A1
(43) Pub. Date: Mar. 25, 2010

(54) APPARATUS AND METHOD FOR MANUFACTURING SEMICONDUCTOR ELEMENT AND SEMICONDUCTOR ELEMENT MANUFACTURED BY THE METHOD

(75) Inventor: Hisao Ochi, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/516,805

(22) PCT Filed: Oct. 4, 2007
(86) PCT No.: PCT/JP2007/069467

§ 371 Date: May 29, 2009

(30) Foreign Application Priority Data
Dec. 1, 2006 (JP) 2006-325866

(51) Int. Cl. H01L 21/46

(52) U.S. Cl. 438/758; 118/723 E; 257/E21.482

(57) ABSTRACT

An apparatus for manufacturing a semiconductor element includes processing chambers arranged to accommodate a flexible substrate which is step-transferred by one effective region each time; a first electrode and a second electrode which are provided in the processing chamber; and a mask portion having an opening so as to expose the effective region when each effective region of the flexible substrate is transferred between the first electrode and the second electrode. Each processing chamber includes a plasma processing portion arranged to perform plasma processing on an effective region of the flexible substrate which is exposed from the opening of the mask portion, a first standby portion which overlaps a carry-in side of the mask portion, and in which an effective region of the flexible substrate prior to the plasma processing is positioned, and a second standby portion which overlaps a carry-out side of the mask portion, and in which an effective region of the flexible substrate after the plasma process is positioned.

### BACKGROUND OF THE INVENTION

1. Field of the Invention

The present invention relates to an apparatus and a method for manufacturing a semiconductor element, and a semiconductor element manufactured by the manufacturing method. More particularly, the present invention relates to a manufacturing technique of a semiconductor element which is manufactured by successively forming a thin film on a long flexible substrate.

2. Description of the Related Art

Electronic devices such as an integrated circuit, a liquid crystal display device, an organic electroluminescence element, and a solar cell are manufactured by using, for example, a plasma processing apparatus such as a plasma CVD (Chemical Vapor Deposition) apparatus for depositing a semiconductor film and the like by using plasma, and a plasma etching apparatus for etching an etching film by using plasma.

As a method for manufacturing such an electronic device on a flexible substrate, a roll-to-roll method and a stepping roll method for continuously processing a long flexible substrate in the above plasma processing device have been used in practical applications.

The roll-to-roll method is a method in which a processing substrate is continuously moved without stopping in, for example, a plasma processing apparatus having a plurality of deposition chambers arranged in line, so that a predetermined thin film is deposited in each deposition chamber and each thin film is sequentially laminated. On the other hand, the stepping roll method is a method in which a processing substrate is stopped in each deposition chamber of the above plasma processing apparatus so that a thin film is deposited thereon, and the deposited portion of the processing substrate is then step-transferred to the adjacent next deposition chamber for the next deposition process. In this stepping roll method, each deposition chamber is hermetically sealed during the deposition process. Therefore, counter diffusion of a reaction gas between the deposition chambers is suppressed as compared to the roll-to-roll method.

For example, Japanese Published Patent Application No. 2000-216094 discloses a stepping roll-type thin-film manufacturing apparatus which is formed by a feeding preliminary vacuum chamber, a wind-up preliminary vacuum chamber for winding up a flexible substrate having films deposited thereon, a plurality of deposition chambers provided therebetween, a sidewall seal portion for opening and closing a communication hole to an adjacent deposition chamber, and an inter-chamber seal portion for opening and closing a communicating hole between the deposition chambers. The feeding preliminary vacuum chamber and the wind-up preliminary vacuum chamber have guide rolls for changing the transfer direction of the flexible substrate between a feed roll or a wind-up roll and the communicating hole so that the transfer direction becomes parallel to the sidewall near the communicating hole. Closing the sidewall seal portion and the inter-chamber seal portion completely vacuum-seals each deposition chamber, and opening these seal portions enables the step transfer. More specifically, it is described that this thin-film manufacturing apparatus is an apparatus for, for example, successively manufacturing a thin-film photoelectric transducer such as a thin film solar cell, and that this thin-film manufacturing apparatus can manufacture a high deposition-quality thin film free from the influence of impurities at low cost.

Incidentally, the following problems are possible when an active matrix substrate which forms an active matrix driving liquid crystal display device and which has, for example, a thin film transistor (hereinafter, referred to as the “TFT”) formed as a switching element at every pixel as a minimum unit of image is manufactured by the above stepping roll method.

FIG. 11 is a transverse sectional view of a conventional stepping roll-type thin-film manufacturing apparatus 150. FIG. 12 is a top view showing a flexible substrate 110 which is step-transferred in the thin-film manufacturing apparatus 150.

As shown in FIGS. 11 and 12, this thin-film manufacturing apparatus 150 includes a wind-off chamber M1, a first deposition chamber C1, a second deposition chamber C2, a third deposition chamber C3, and a wind-up chamber M2, which are provided sequentially from left to right in the figure. The thin-film manufacturing apparatus 150 is configured so that the flexible substrate 110 wound up on a wind-off roll R1 in the wind-off chamber M1 is subjected to a film deposition process while being sequentially step-transferred to the first deposition chamber C1, the second deposition chamber C2, and the third deposition chamber C3, and is then wound up on a wind-up roll R2 in the wind-up chamber M2.

Moreover, as shown in FIGS. 11 and 12, each deposition chamber C1 through C3 includes a heater electrode H provided as an anode electrode, a cathode electrode S positioned so as to face the heater electrode H, and a deposition mask 123 having a frame shape so as to cover a region other than an effective region (deposition region) E of the flexible substrate 110 which is step-transferred between the heater electrode H and the cathode electrode S. Each deposition chamber C1 through C3 is configured so that a film deposition process using plasma generated between the heater electrode H and the cathode electrode S is performed through an opening of the mask 123.

In manufacturing of an active matrix substrate, variations in TFT characteristics in the substrate plane reduce the display quality of a liquid crystal display device. Therefore, in order to suppress variations in characteristics such as the thickness and the quality of each thin film of the TFTs formed on the flexible substrate 110, such as a semiconductor film, an insulating film, and a conductive film, a region where the thin films are deposited on the flexible substrate 110 is limited by the deposition mask 123. As a result, an effective region E where the thin films are deposited, and a surrounding ineffective region (not shown) where no thin film is deposited are defined on the flexible substrate 110. Moreover, it is considered that uniform film deposition is difficult near the inner wall of each deposition chamber C1, C2, and C3 due to non-uniformity of plasma. It is therefore necessary to position the inner peripheral end of the frame-shaped deposition mask 123 at a certain distance from the inner wall of each deposition chamber C1, C2, and C3. As shown in FIG. 12, this reduces the proportion of the effective region E in the whole substrate in the case of the flexible substrate 110 which is step-transferred.

### SUMMARY OF THE INVENTION

In view of the above problems, preferred embodiments of the present invention increase the area of effective regions in a flexible substrate to be plasma-processed by step transfer as much as possible.

In a preferred embodiment of the present invention, at least three effective regions of a flexible substrate are accommodated in a processing chamber, and an inner one of the accommodated effective regions is plasma-processed.

More specifically, an apparatus for manufacturing a semiconductor element according to a preferred embodiment of the present invention includes: a processing chamber arranged to accommodate at least a portion of a flexible substrate which has a plurality of effective regions arranged therein along a length direction, and which is step-transferred by one effective region each time; a first electrode and a second electrode which are provided in the processing chamber so as to face each other; and a mask portion provided between the first electrode and the second electrode, and having an opening so as to expose the effective region when each effective region of the flexible substrate is step-transferred between the first electrode and the second electrode. Plasma processing using plasma generated between the first electrode and the second electrode is performed on each effective region of the flexible substrate through the opening of the mask portion, thereby manufacturing a semiconductor element. The processing chamber includes: a plasma processing portion arranged to perform the plasma processing on an effective region of the flexible substrate which is exposed from the opening of the mask portion; a first standby portion which is provided on a carry-in side of the plasma processing portion so as to overlap the mask portion, and in which an effective region of the flexible substrate prior to the plasma processing is positioned; and a second standby portion which is provided on a carry-out side of the plasma processing portion so as to overlap the mask portion, and in which an effective region of the flexible substrate after the plasma process is positioned.

According to the above structure, the processing chamber arranged to accommodate at least a portion of the flexible substrate which is step-transferred by one effective region each time includes: a plasma processing portion positioned at the opening of the mask portion and arranged to perform the plasma processing on each effective region of the flexible substrate through the opening; the first standby portion which is positioned so as to overlap one side (the carry-in side) of the mask portion, and in which an effective region of the flexible substrate prior to the plasma processing in the plasma processing portion is positioned; and the second standby portion which is positioned so as to overlap the other side (the carry-out side) of the mask portion, and in which an effective region of the flexible substrate after the plasma process in the plasma processing portion is positioned. Therefore, the effective region is positioned in a region which was conventionally an ineffective region overlapping the mask portion in the deposition chamber. This can reduce the distance between the effective regions in the flexible substrate, and therefore can increase the area of the effective regions in the flexible substrate to be plasma-processed by step transfer as much as possible.

The processing chamber may be configured so as to accommodate at least adjacent three effective regions of the flexible substrate.

According to the above structure, an inner one of the at least adjacent three effective regions of the flexible substrate accommodated in the processing chamber is positioned in the plasma processing portion, at least one of the at least adjacent three effective regions which is located on the carry-in side is positioned in the first standby portion, and at least one of the at least adjacent three effective regions which is located on the carry-out side is positioned in the second standby portion. Therefore, the functions, effects and advantages of the present invention are achieved specifically.

A protruding wall, which is in contact with a region between the effective regions of the flexible substrate to provide isolation from the plasma processing portion, may be provided along an inner peripheral end and an outer peripheral end of the mask portion.

According to the above structure, the protruding wall provided along the inner peripheral end and the outer peripheral end of the mask portion prevents plasma and the like used in the plasma processing in the plasma processing portion from entering the effective region of the flexible substrate prior to the plasma processing, which is located in the first standby portion, and the effective region of the flexible substrate after the plasma processing, which is located in the second standby portion. This enables the quality of a manufactured semiconductor element to be improved.

Multiple processing chambers, such as the one described above, may be successively arranged along the length direction of the flexible substrate.

According to the above structure, plasma processing is performed in each processing chamber. Therefore, in the case where the plasma processing is, for example, plasma CVD processing, each processing chamber formed by a plasma CVD apparatus or the like is successively arranged along the length direction of the flexible substrate, and the flexible substrate is step-transferred and plasma-processed in each processing chamber. Accordingly, a thin film deposited by plasma CVD (Chemical Vapor Deposition) in each processing chamber is successively laminated on each effective region of the flexible substrate.

A carry-in portion for carrying the flexible substrate into the processing chamber, and a carry-out portion for carrying the flexible substrate out of the processing chamber may be provided in the processing chamber, and an opening/closing gate for holding a region located between the effective regions of the flexible substrate to hermetically seal the processing chamber may be provided in each of the carry-in portion and the carry-out portion.

According to the above structure, in every step transfer, the region between the effective regions of the flexible substrate is held by the opening/closing gate provided in each of the carry-in portion and the carry-out portion of the processing chamber, whereby airtightness of the processing chamber can be maintained. Accordingly, the functions, effects and advantages of the present invention are achieved specifically.

A heater for heating the flexible substrate may be provided in the first standby portion.

According to the above structure, the flexible substrate to be plasma-processed in the plasma processing portion is preheated by the heater provided in the first standby portion. This can reduce the tact time of the apparatus.

The processing chamber may be configured so that a deposition process is performed by plasma CVD.

According to the above structure, a thin film is deposited on each effective region of the flexible substrate by plasma CVD. Therefore, the functions, effects and advantages of the present invention are achieved specifically.

A method for manufacturing a semiconductor element according to another preferred embodiment of the present invention includes: a transfer step of step-transferring a flexible substrate, which has a plurality of effective regions arranged along a length direction, by one effective region each time at least in a processing chamber; and a plasma processing step of performing plasma processing in the processing chamber on each effective region of the flexible substrate step-transferred in the transfer step. In the plasma processing step, at least adjacent three effective regions of the flexible substrate are accommodated in the processing chamber, and an inner one of the accommodated at least three effective regions is plasma-processed.

According to the above method, in the transfer step, the flexible substrate having the plurality of effective regions arranged along the length direction is step-transferred by one effective region each time. Therefore, at least adjacent three effective regions of the flexible substrate are accommodated in the deposition chamber. Then, in the plasma processing step, an inner one of the at least adjacent three effective regions of the flexible substrate accommodated in the deposition chamber is plasma-processed. Of the at least adjacent three effective regions of the flexible substrate, at least one effective region located on the carry-in side and at least one effective region located on the carry-out side are accommodated in the deposition chamber, but are not plasma-processed. Accordingly, an ineffective region around each effective region of the flexible substrate can be reduced, and the distance between the effective regions can be reduced in the flexible substrate. As a result, the area of the effective regions is increased as much as possible in the flexible substrate to be plasma-processed by step transfer.

Moreover, a semiconductor element according to a preferred embodiment of the present invention is manufactured by the manufacturing method of the semiconductor element according to another preferred embodiment of the present invention.

According to the above structure, the area of each effective region in the flexible substrate on which a semiconductor element is to be manufactured is increased as much as possible. Therefore, the functions, effects and advantages of the present invention are achieved specifically.

According to various preferred embodiments of the present invention, at least three effective regions of a flexible substrate are accommodated in a processing chamber, and an inner one of the accommodated effective regions is plasma-processed. This enables the area of the effective regions to be increased as much as possible in the flexible substrate to be plasma-processed by step transfer.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a transverse sectional view showing a thin-film manufacturing apparatus 50 according to a first preferred embodiment of the present invention.

FIG. 2 is a top view showing a flexible substrate 10 which is step-transferred in the thin-film manufacturing apparatus 50.

FIG. 3 is a transverse sectional view showing a deposition chamber Cxa of the thin-film manufacturing apparatus 50.

FIG. 4 is a top view showing the inside of the deposition chamber Cxa.

FIG. 5 is a first state diagram showing step transfer of the flexible substrate 10 in the thin-film manufacturing apparatus 50.

FIG. 6 is a second state diagram showing step transfer of the flexible substrate 10 in the thin-film manufacturing apparatus 50.

FIG. 7 is a third state diagram showing step transfer of the flexible substrate 10 in the thin-film manufacturing apparatus 50.

FIG. 8 is a cross-sectional view showing the flexible substrate 10 having thin films laminated thereon.

FIG. 9 is a transverse sectional view showing a processing chamber Cxb of a thin-film manufacturing apparatus according to a second preferred embodiment of the present invention.

FIG. 10 is a bottom view of a mask portion 23b of the processing chamber Cxb.

FIG. 11 is a transverse sectional view showing a conventional stepping roll-type thin-film manufacturing apparatus 150.

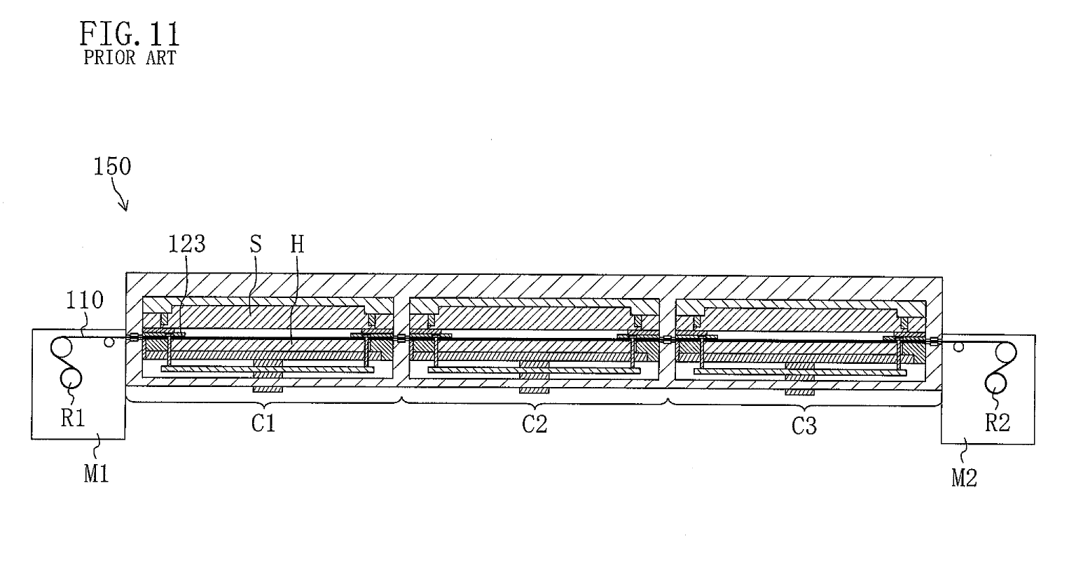

FIG. 12 is a top view showing a flexible substrate 110 which is step-transferred in the thin-film manufacturing apparatus 150.

### DETAILED DESCRIPTION OF THE PREFERRED EMBODIMENTS

Hereinafter, preferred embodiments of the present invention will be described in detail based on the accompanying drawings. Note that the present invention is not limited to the preferred embodiments described below.

### First Preferred Embodiment

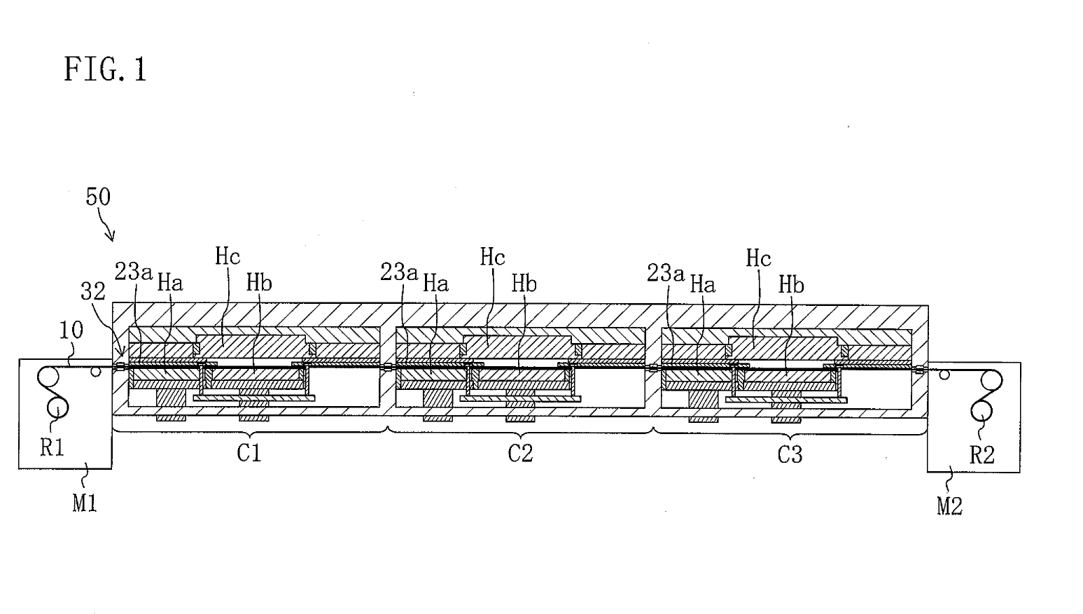

FIGS. 1 through 8 show a first preferred embodiment of a manufacturing apparatus and a manufacturing method of a semiconductor element according to the present invention, and a semiconductor element manufactured by the manufacturing method. Note that, in each preferred embodiment described below, a thin-film manufacturing apparatus for depositing a semiconductor film and the like on a flexible substrate which is step-transferred preferably is shown as an example of the semiconductor-element manufacturing apparatus.

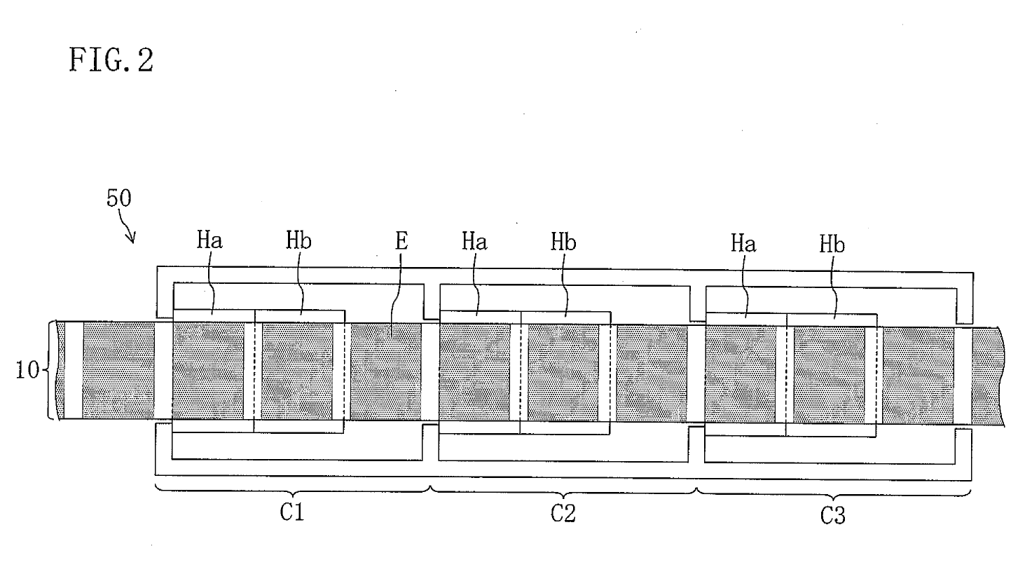

FIG. 1 is a transverse sectional view showing a thin-film manufacturing apparatus 50 of the first preferred embodiment. FIG. 2 is a top view showing a flexible substrate 10 which is step-transferred in the thin-film manufacturing apparatus 50.

As shown in FIG. 1, the thin-film manufacturing apparatus 50 includes a wind-off chamber M1, a first deposition chamber C1, a second deposition chamber C2, a third deposition chamber C3, and a wind-up chamber M2, sequentially from left to right in the figure. The thin-film manufacturing apparatus 50 is configured so that the flexible substrate 10 carried out of the wind-off chamber M1 is subjected to a film deposition process while being sequentially step-transferred to the first deposition chamber C1, the second deposition chamber C2, and the third deposition chamber C3, and is then carried into the wind-up chamber M2.

The flexible substrate 10 which is step-transferred is herein a film substrate having a heat resistance, such as a polyimide resin film. As shown in FIG. 2, a plurality of effective regions E are arranged along a length direction.

As shown in FIG. 1, the wind-off chamber M1 includes a wind-off roll R1 arranged to attach the flexible substrate 10 wound in a roll thereto, and a guide roll arranged to transfer the flexible substrate 10 wound off from the wind-off roll R1 to the first deposition chamber C1.

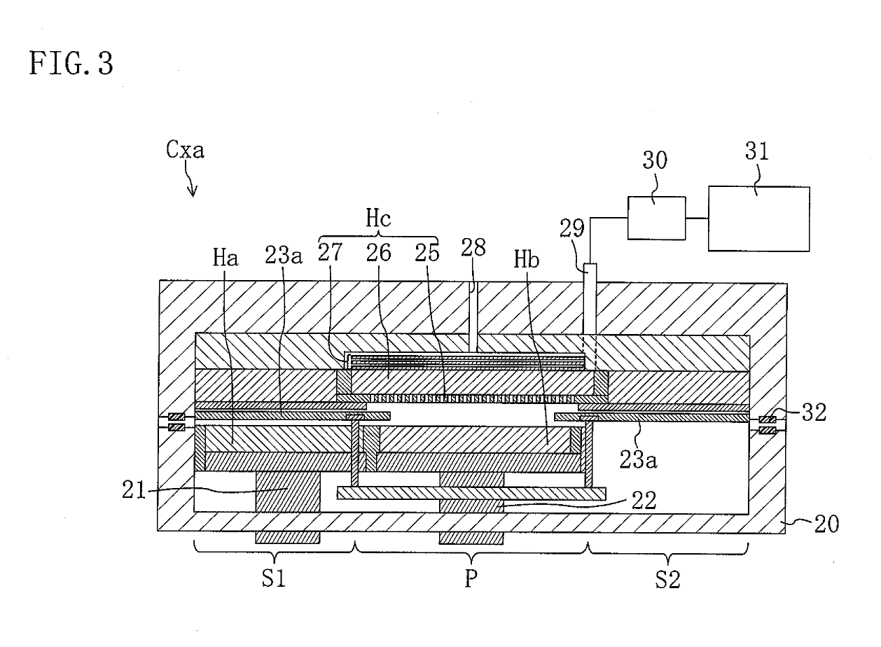

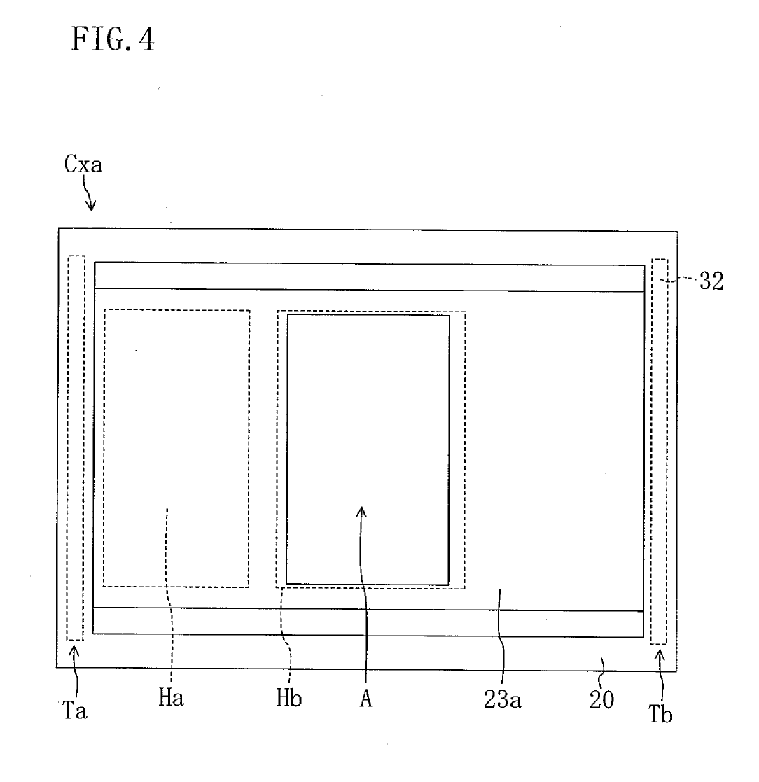

As shown in FIG. 1, the first deposition chamber C1, the second deposition chamber C2, and the third deposition chamber C3 are deposition chambers having a similar structure to each other, and are shown as a deposition chamber Cxa in FIG. 3. FIG. 3 is a transverse sectional view showing the deposition chamber Cxa, and FIG. 4 is a top view showing the inside of the deposition chamber Cxa.

A frame-shaped mask portion 23a is provided in each deposition chamber C1 through C3, that is, the deposition chamber Cxa. As shown in FIGS. 3 and 4, the deposition chamber Cxa includes a first standby portion S1, a plasma processing portion P, and a second standby portion S2, sequentially from left to right in the figure. Note that the mask portion 23a is made of a ceramic material or the like, and has a rectangular opening A in the middle. The shape of the opening A of the mask portion 23a corresponds to the shape of each effective region E of the flexible substrate 10.

As shown in FIG. 3, the first standby portion S1 is positioned on the carry-in side of the mask portion 23a, and includes a heater electrode Ha having a built-in heater. The heater electrode Ha is configured so as to be able to heat the flexible substrate 10 placed on its surface. The heater electrode Ha is herein configured so as to be able to move up and down by an elevating mechanism 21.

As shown in FIG. 3, the plasma processing portion P includes a first electrode (anode electrode) Hb and a second electrode (cathode electrode) Hc which are positioned in the opening A of the mask portion 23a so as to face each other.

As shown in FIG. 3, the first electrode Hb has a built-in heater, and is configured so as to be able to heat the flexible substrate 10 placed on its surface, and so as to be able to move up and down by an elevating mechanism 22 so that the distance to the second electrode Hc can be changed.

As shown in FIG. 3, the second electrode Hc includes a shower plate 25, an electrode main body 26, and a shower head 27, and is attached to a top wall of an inner wall 20 with an insulating member interposed therebetween.

The electrode main body 26 is connected to a high frequency power source 31 through a power-feeding member 29 and a matching device 30, and is configured so as to receive high frequency power from the high frequency power source 31. Note that the heater electrode Ha, the first electrode Hb, and the inner wall 20 are connected to a ground potential.

The shower plate 25 has a plurality of through holes, and is configured so that a deposition gas is introduced into the plasma processing portion P through each through hole.

The shower head 27 has a plurality of diffusion plates each having a multiplicity of through holes and positioned so as to face each other, and is connected to a deposition gas source (not shown) through a deposition gas supply port 28. The shower head 27 is configured so as to diffuse the deposition gas to supply the deposition gas to the electrode main body 26.

As shown in FIG. 3, the second standby portion S2 is positioned on the carry-out side of the mask portion 23a.

As shown in FIG. 4, the deposition chamber Cxa is further provided with a carry-in portion Ta for carrying the flexible substrate 10 into the deposition chamber Cxa, and a carry-out portion Tb for carrying the flexible substrate 10 out of the deposition chamber Cxa. Each of the carry-in portion Ta and the carry-out portion Tb is provided with a opening/closing gate 32 for holding an ineffective region located between the effective regions E of the flexible substrate 10 to hermetically seal the chamber, thereby maintaining airtightness of the chamber. Note that the opening/closing gate 32 is, for example, a pair of elongated plate-like bodies made of a material having a heat resistance such as a fluororesin, and having an opening/closing mechanism.

The deposition chamber Cxa is further provided with an evacuation system (not shown) for evacuating the deposition chamber Cxa and discharging a deposition gas.

When the high frequency power from the high frequency power source 31 is applied to the second electrode Hc in the deposition chamber Cxa having the above structure, a deposition gas introduced into the deposition chamber Cxa is plasmatized by capacitive-coupling glow discharge between the first electrode Hb and the second electrode Hc. A reaction product resulting from plasmatization of the deposition gas reaches the surface of the effective region E of the flexible substrate 10 heated by the heater electrode Ha and the first electrode Hb, and is deposited thereon. As a result, a thin film is formed on the effective region E of the flexible substrate 10.

As shown in FIG. 1, the wind-up chamber M2 includes a guide roll arranged to transfer the flexible substrate 10 transferred from the third deposition chamber C3, and a wind-up roll R2 arranged to wind up the transferred flexible substrate 10 in a roll form.

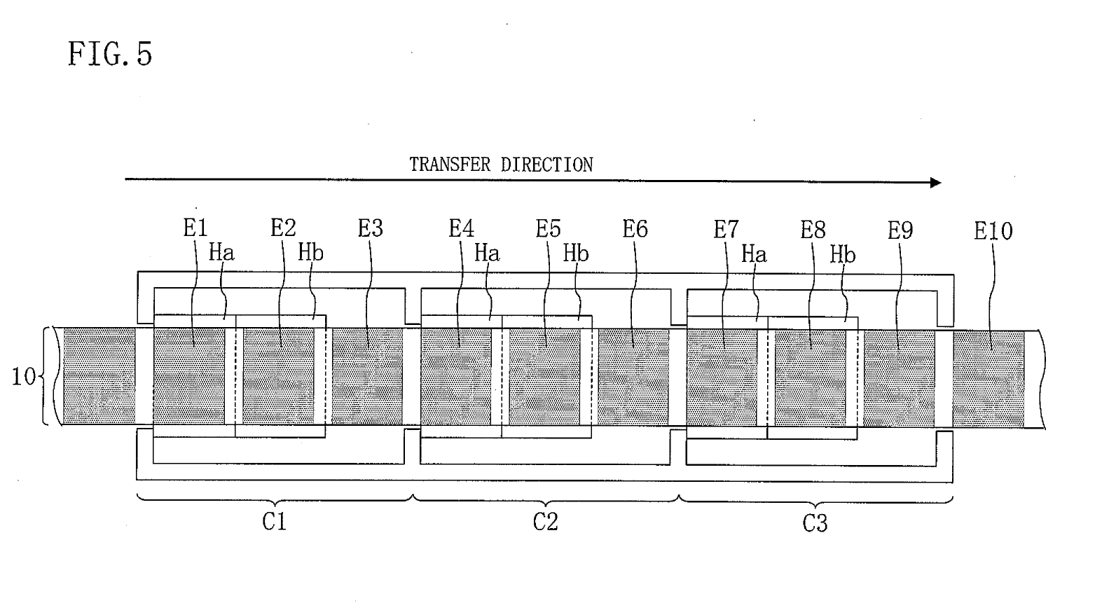

Hereinafter, overall operation in each deposition chamber C1 through C3 of the thin-film manufacturing apparatus 50 of the above structure will be described with reference to FIGS. 5 through 7.

First, as shown in FIG. 5, an effective region E2 of the flexible substrate 10 is positioned on the first electrode Hb (the plasma processing portion P) in the first deposition chamber C1. Therefore, a first thin film (e.g., a gate insulating film 11 described below) is deposited on the surface of the effective region E2. At this time, an effective region E1 of the flexible substrate 10 is positioned on the heater electrode Ha (the first standby portion S1) and heated. An effective region E3 of the flexible substrate 10 is positioned in the second standby portion S2, and is therefore in a standby state, a state before being carried into the second deposition chamber C2. In the second deposition chamber C2, an effective region E5 of the flexible substrate 10 is positioned on the first electrode Hb (the plasma processing portion P). Therefore, a second thin film (e.g., a first semiconductor film 12 described below) is deposited on the surface of the effective region E5. At this time, an effective region E4 of the flexible substrate 10 is positioned on the heater electrode Ha (the first standby portion S1) and heated. An effective region E6 of the flexible substrate 10 is positioned in the second standby portion S2, and is therefore in a standby state, a state before being carried into the third deposition chamber C3. Moreover, in the third deposition chamber C3, an effective region E8 of the flexible substrate 10 is positioned on the first electrode Hb (the plasma processing portion P). Therefore, a third thin film (e.g., a second semiconductor film 13 described below) is deposited on the surface of the effective region E8. At this time, an effective region E7 of the flexible substrate 10 is positioned on the heater electrode Ha (the first standby portion S1) and heated. An effective region E9 of the flexible substrate 10 is positioned in the second standby portion S2, and is therefore in a standby state, a state before being carried into the wind-up chamber M2.

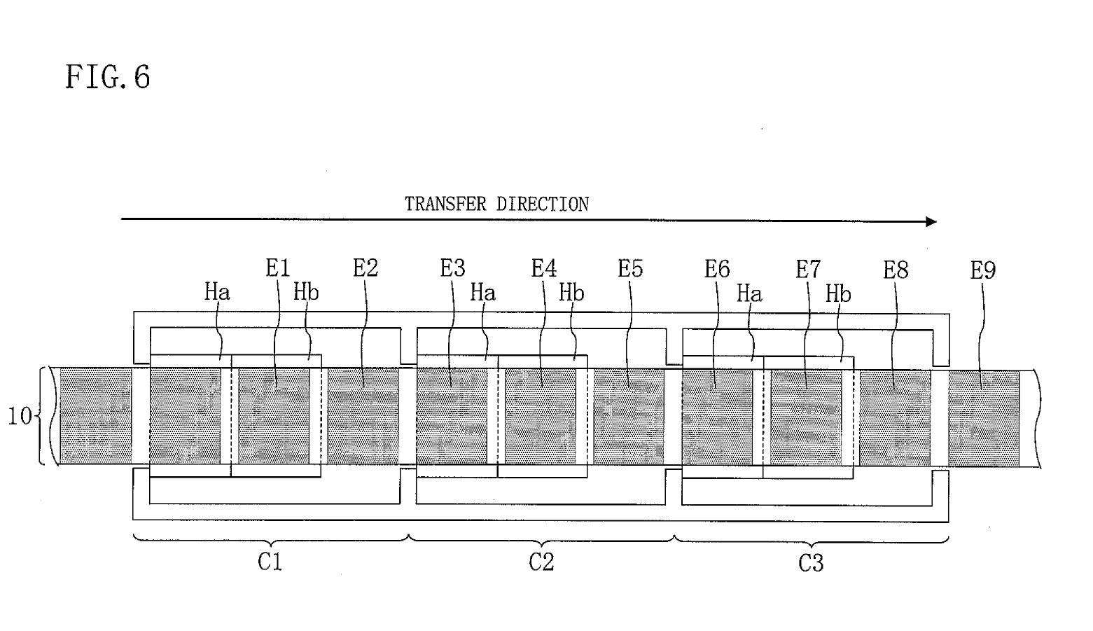

Next, as shown in FIG. 6, the flexible substrate 10 is transferred by one effective region E to the right. In the first deposition chamber C1, the effective region E1 of the flexible substrate 10 is positioned on the first electrode Hb (the plasma processing portion P). Therefore, a first thin film (e.g., a gate insulating film 11 described below) is deposited on the surface of the effective region E1. At this time, an effective region E of the flexible region 10 located next to the effective region E1 on the carry-in side (the left side) is positioned on the heater electrode Ha (the first standby portion S1) and heated. The effective region E2 of the flexible substrate 10 is positioned in the second standby portion S2, and is therefore in a standby state, a state before being carried into the second deposition chamber C2. In the second deposition chamber C2, the effective region E4 of the flexible substrate 10 is positioned on the first electrode Hb (the plasma processing portion P). Therefore, a second thin film (e.g., a first semiconductor film 12 described below) is deposited on the surface of the effective region E4. At this time, the effective region E3 of the flexible substrate 10 is positioned on the heater electrode Ha (the first standby portion S1) and heated. The effective region E5 of the flexible substrate 10 is positioned in the second standby portion S2, and is therefore in a standby state, a state before being carried into the third deposition chamber C3. Moreover, in the third deposition chamber C3, the effective region E7 of the flexible substrate 10 is positioned on the first electrode Hb (the plasma processing portion P). Therefore, a third thin film (e.g., a second semiconductor film 13 described below) is deposited on the surface of the effective region E7. At this time, the effective region E6 of the flexible substrate 10 is positioned on the heater electrode Ha (the first standby portion S1) and heated. The effective region E8 of the flexible substrate 10 is positioned in the second standby portion S2, and is therefore in a standby state, a state before being carried into the wind-up chamber M2.

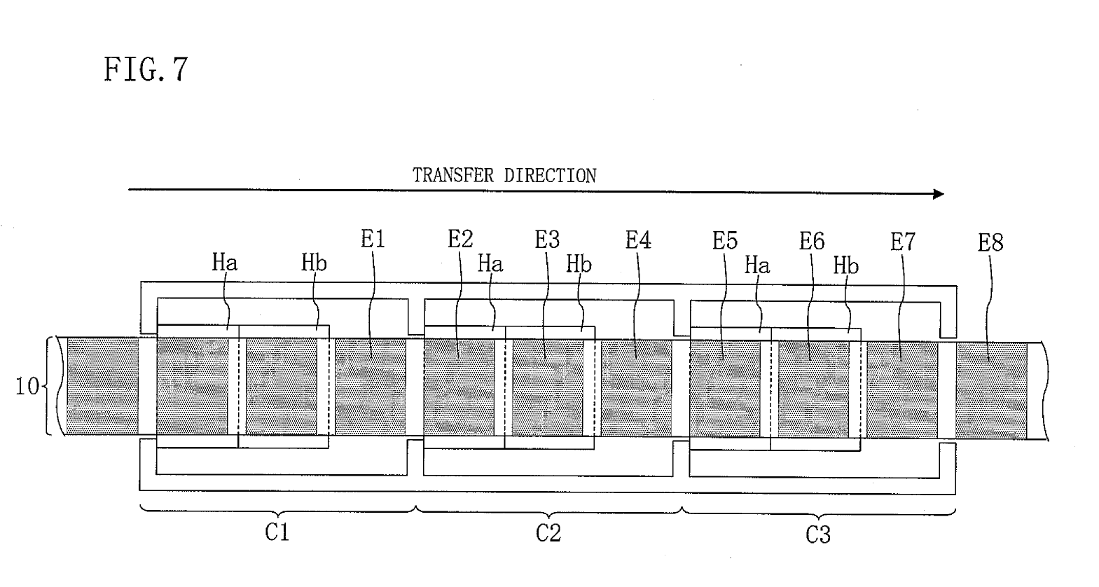

Next, as shown in FIG. 7, the flexible substrate 10 is transferred by one effective region E to the right. In the first deposition chamber C1, the effective region E of the flexible region 10 located next to the effective region E1 on the carry-in side (the left side) is positioned on the first electrode Hb (the plasma processing portion P). Therefore, a first thin film (e.g., a gate insulating film 11 described below) is deposited on the surface of this effective region E. At this time, an effective region E of the flexible substrate 10 located two effective regions away from the effective region E1 on the carry-in side (the left side) is positioned on the heater electrode Ha (the first standby portion S1) and heated. The effective region E1 of the flexible region 10 is positioned in the second standby portion S2, and is therefore in a standby state, a state before being carried into the second deposition chamber C2. In the second deposition chamber C2, the effective region E3 of the flexible substrate 10 is positioned on the first electrode Hb (the plasma processing portion P). Therefore, a second thin film (e.g., a first semiconductor film 12 described below) is deposited on the surface of the effective region E3. At this time, the effective region E2 of the flexible substrate 10 is positioned on the heater electrode Ha (the first standby portion S1) and heated. The effective region E4 of the flexible substrate 10 is positioned in the second standby portion S2, and is therefore in a standby state, a state before being carried into the third deposition chamber C3. Moreover, in the third deposition chamber C3, the effective region E6 of the flexible substrate 10 is positioned on the first electrode Hb (the plasma processing portion P). Therefore, a third thin film (e.g., a second semiconductor film 13 described below) is deposited on the surface of the effective region E6. At this time, the effective region E5 of the flexible substrate 10 is positioned on the heater electrode Ha (the first standby portion S1) and heated. The effective region E7 of the flexible substrate 10 is positioned in the second standby portion S2, and is therefore in a standby state, a state before being carried into the wind-up chamber M2.

Hereinafter, a method for manufacturing a TFT (semiconductor element) by depositing a gate insulating film, a semiconductor film, and the like on the flexible substrate 10 by using the thin-film manufacturing apparatus 50 of the above structure will be described.

First, by a sputtering method such as a roll-to-roll method, a silicon oxide film is deposited with a thickness of about 1,000 nm on the flexible substrate 10, such as a polyimide film which is 500 mm wide, 50 m long, and 100 μm thick, to form a base coat film, for example.

Next, by a sputtering method such as a roll-to-roll method, a metal film such as aluminum is deposited with a thickness of about 150 nm on the flexible substrate 10 having the base coat film formed thereon. The metal film is then patterned by a photolithography technique to form a gate electrode and the like.

The flexible substrate 10, which has the gate electrode and the like formed thereon and has been wound up in a roll form, is attached to the wind-off roll R1 in the wind-off chamber M1, and an end of the substrate is attached to the wind-up roll R2 in the wind-up chamber M2 via the first deposition chamber C1, the second deposition chamber C2, and the third deposition chamber C3. The flexible substrate 10 is set in the thin-film manufacturing apparatus 50 in this manner.

Then, a transfer step for step-transferring the set flexible substrate 10 by one effective region E each time, and a plasma processing step for plasma-processing each step-transferred effective region E are repeated alternately.

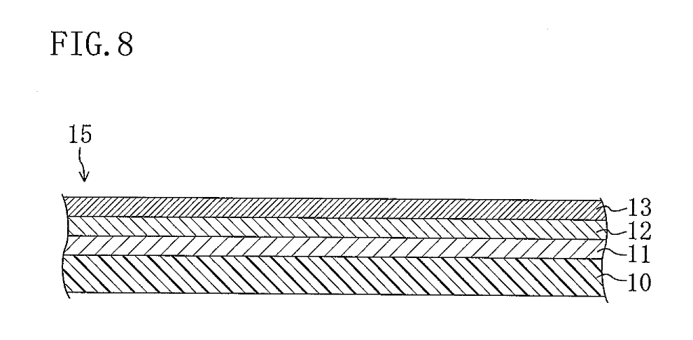

Here, in the first deposition chamber C1, high frequency power of, for example, 27.12 MHz is applied to the second electrode Hc so that the power density per unit area of the electrode becomes 0.5 W/cm². A mixed gas containing monosilane (SiH₄), ammonia (NH₃), and nitrogen (N₂) is introduced through the deposition gas supply port 28, the deposition pressure (discharge pressure) is set to 200 Pa, and the substrate temperature is raised to 220° C. by the heater electrode Ha and the first electrode Hb. A silicon nitride film is thus deposited with a thickness of about 400 nm on the flexible substrate 10 to form a gate insulating film 11 (see FIG. 8).

Moreover, in the second deposition chamber C2, high frequency power of, for example, 27.12 MHz is applied to the second electrode Hc so that the power density per unit area of the electrode becomes 0.25 W/cm². A mixed gas containing monosilane (SiH₄) and hydrogen (H₂) is introduced through the deposition gas supply port 28, the deposition pressure (discharge pressure) is set to 150 Pa, and the substrate temperature is raised to 220° C. by the heater electrode Ha and the first electrode Hb. An amorphous silicon film is thus deposited with a thickness of about 150 nm on the flexible substrate 10 having the gate insulating film 11 formed in the first deposition chamber C1, thereby forming a first semiconductor film 12 (see FIG. 8).

Moreover, in the third deposition chamber C3, high frequency power of, for example, 27.12 MHz is applied to the second electrode Hc so that the power density per unit area of the electrode becomes 0.08 W/cm². A mixed gas containing monosilane (SiH₄), phosphine (PH₃), and argon (Ar) is introduced through the deposition gas supply port 28, the deposition pressure (discharge pressure) is set to 133 Pa, and the substrate temperature is raised to 220° C. by the heater electrode Ha and the first electrode Hb. An n+ amorphous silicon film is thus deposited with a thickness of about 50 nm on the flexible substrate 10 having the gate insulating film 11 and the first semiconductor film 12 sequentially formed in the first deposition chamber C1 and the second deposition chamber C2, thereby forming a second semiconductor film 13 (see FIG. 8).

In this manner, a semiconductor element 15 having the gate insulating film 11, the first semiconductor film 12, and the second semiconductor film 13 sequentially laminated on the flexible substrate 10 as shown in FIG. 8 is wound up by the wind-up roll R2 in the wind-up chamber M2.

Next, the laminated film of the gate insulating film 11, the first semiconductor film 12, and the second semiconductor film 13 is patterned into an island shape by a photolithography technique such as a roll-to-roll method to form a semiconductor layer.

Moreover, by a sputtering method such as a roll-to-roll method, a metal film such as aluminum is deposited with a thickness of about 150 nm on the flexible substrate 10 having the semiconductor layer formed thereon. The metal film is then patterned by a photolithography technique to form a source electrode, a drain electrode, and the like.

Finally, the flexible substrate 10 having the source electrode, the drain electrode, and the like formed thereon is subjected to a roll-to-roll method or the like to etch the n+ amorphous silicon layer of the semiconductor layer by using the source electrode and the drain electrode as a mask, thereby patterning a channel portion.

A semiconductor element having a TFT formed on the flexible substrate 10 can be manufactured in this manner.

Thereafter, by a CVD method such as a roll-to-roll method, a silicon nitride film or the like is deposited on the flexible substrate 10 having the TFT formed thereon, and a contact hole is patterned on the drain electrode by a photolithography technique to form a protective insulating film. Moreover, by a sputtering method such as a roll-to-roll method, an ITO (Indium Tin Oxide) film is deposited with a thickness of about 100 nm over the flexible substrate 10 having the protective insulating film formed thereon, and is then patterned by a photolithography technique to form a pixel electrode. An active matrix substrate of an active matrix driving liquid crystal display device can be manufactured in this manner.

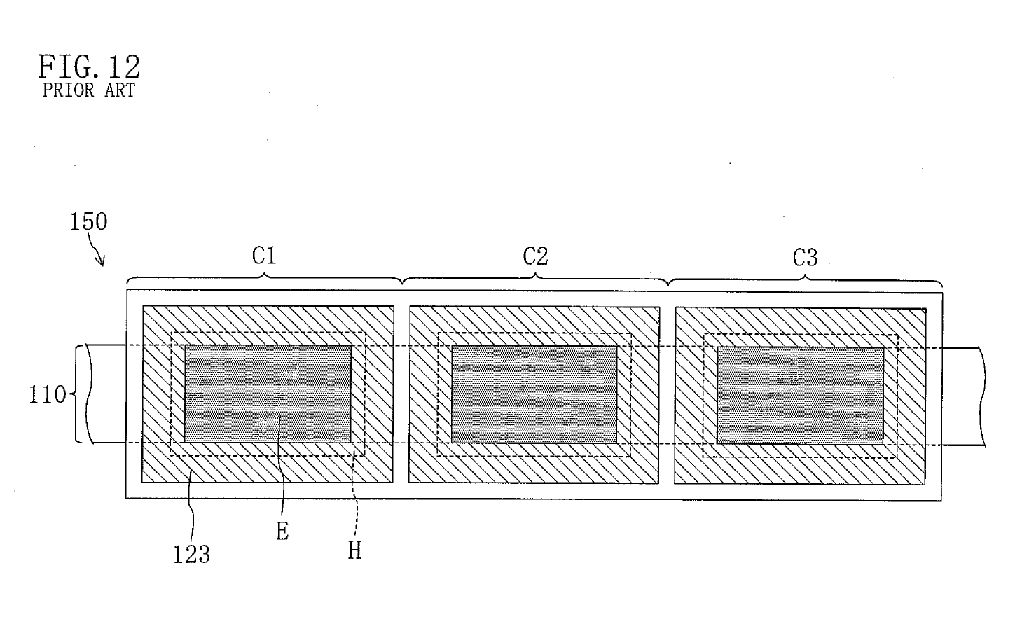

As described above, according to the thin-film manufacturing apparatus 50 of the present preferred embodiment and the manufacturing method using this apparatus, each deposition chamber C1 through C3 for accommodating at least a portion of the flexible substrate 10 which is step-transferred by one effective region E each time includes: the plasma processing portion P positioned at the opening A of the mask portion 23a, for plasma-processing each effective region E of the flexible substrate 10 through the opening A; the first standby portion S1 which is positioned so as to overlap one side (the carry-in side) of the mask portion 23a, and in which the effective region E of the flexible substrate 10 prior to the plasma processing in the plasma processing portion P is positioned; and the second standby portion S2 which is positioned so as to overlap the other side (the carry-out side) of the mask portion 23a, and in which the effective region E of the flexible substrate 10 after the plasma processing in the plasma processing portion P is positioned. Therefore, the effective region is positioned in a region which was conventionally (see FIG. 12) an ineffective region overlapping the mask portion 123 in each deposition chamber C1 through C3.

In other words, in the transfer step, the flexible substrate 10 having a plurality of effective regions E arranged along the length direction is step-transferred by one effective region E each time. Therefore, adjacent three effective regions of the flexible substrate 10 are accommodated in each deposition chamber C1 through C3. In the plasma processing step, the middle one E of the adjacent three effective regions E of the flexible substrate 10 accommodated in each deposition chamber C1 through C3 is plasma-processed. Of the adjacent three effective regions E of the flexible substrate 10, the effective region E located on the carry-in side and the effective region E located on the carry-out side are accommodated in each deposition chamber C1 through C3, but are not plasma-processed. Accordingly, an ineffective region around each effective region E of the flexible substrate 10 can be reduced.

As a result, the distance between the effective regions E can be reduced in the flexible substrate 10, whereby the area of the effective regions E can be increased as much as possible in the flexible substrate 10 to be plasma-processed by step transfer.

Moreover, the present preferred embodiment was described with respect to an example in which adjacent three effective regions of the flexible substrate 10 are accommodated in each deposition chamber C1 through C3. In preferred embodiments of the present invention, however, four or more effective regions E of the flexible substrate may accommodated in each deposition chamber. Note that, in this case as well, one effective region is positioned in the plasma processing portion P.

Moreover, according to the thin-film manufacturing apparatus 50 of the present preferred embodiment, the deposition chambers C1 through C3 are successively arranged along the length direction of the flexible substrate 10, and a plasma CVD processing is performed in each deposition chamber C1 through C3. Therefore, the gate insulating film 11, the first semiconductor film 12, and the second semiconductor film 13 which are respectively deposited by plasma CVD in the deposition chambers C1 through C3 can be successively laminated on each effective region E of the flexible substrate 10.

Moreover, according to the thin-film manufacturing apparatus 50 of the present preferred embodiment, the heater electrode Ha for heating the flexible substrate 10 is provided in the first standby portion S1. Therefore, the flexible substrate 10 to be plasma-processed in the plasma processing portion P can be preheated by the heater electrode Ha, whereby the tact time of the apparatus can be reduced.

### Second Preferred Embodiment

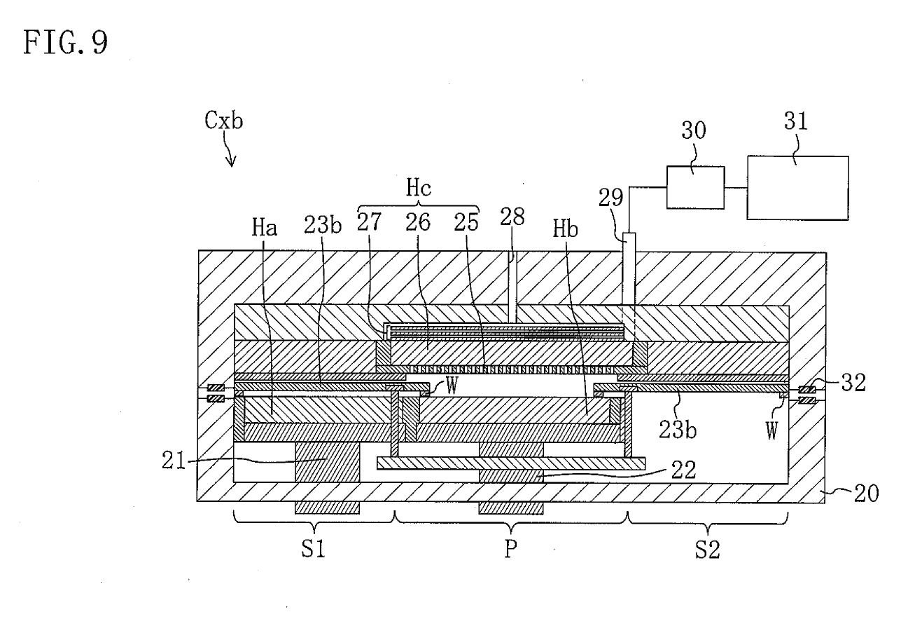

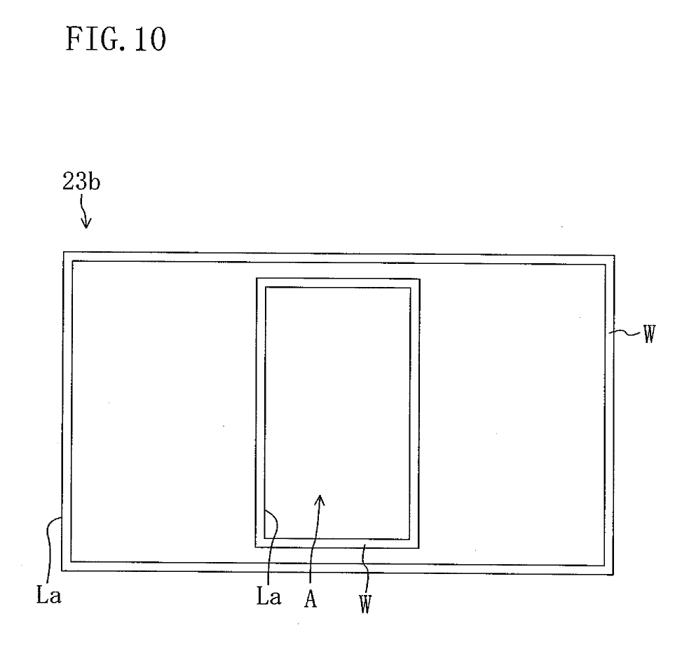

FIG. 9 is a transverse sectional view showing a processing chamber Cxb of a thin-film manufacturing apparatus according to the present preferred embodiment, and FIG. 10 is a bottom view of a mask portion 23b of the processing chamber Cxb. Note that, in the preferred embodiment described below, the same portions as those of FIGS. 1 through 8 are denoted with the same reference numerals and characters, and detailed description thereof will be omitted.

In the first preferred embodiment, the mask portion 23a provided in each deposition chamber C1 through C3 is formed in a planar shape. In the present preferred embodiment, however, as shown in FIGS. 9 and 10, a downward protruding wall W is provided along an inner peripheral end La and an outer peripheral end Lb of the mask portion 23b, and the mask portion 23b is configured so as to be able to move up and down by an elevating mechanism which moves up in the transfer step and moves down in the plasma processing step. According to this structure, the protruding wall W provided along the inner peripheral end La and the outer peripheral end Lb of the mask portion 23b can prevent plasma and the like used in the plasma processing in the plasma processing portion P from entering the effective region E1 (see FIG. 5) of the flexible substrate 10 prior to the plasma processing, which is located in the first standby portion S1, and the effective region E3 (see FIG. 5) of the flexible substrate 10 after the plasma processing, which is located in the second standby portion S2. This can reduce the influence of impurities on the interface of a thin film such as the gate insulating film 11 of the semiconductor element 15, whereby a high quality thin film can be implemented.

Moreover, a plasma CVD process was described as an example of the plasma processing in each of the above preferred embodiments. However, the present invention is applicable also to a plasma cleaning process (apparatus) and a plasma etching process (apparatus).

Moreover, a method in which the second semiconductor film 13 made of an n+ amorphous silicon film is deposited in the third deposition chamber C3 was described as an example in each of the above preferred embodiments. However, a silicon oxide film, a silicon nitride film, or the like may be deposited to form an etch stopper for an etching process for forming the source electrode and the drain electrode.

Note that a method for manufacturing a TFT of an active matrix substrate of a liquid crystal display device was described as an example in each of the above preferred embodiments. However, the present invention is applicable also to manufacturing of other electronic devices such as a plasma display device, an organic electroluminescence element, and a solar cell.

As described above, the present invention can increase the area of effective regions in a flexible substrate as much as possible, and is therefore useful for electronic devices which are manufactured by using a flexible substrate such as a film substrate.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-9. (canceled)

10. An apparatus for manufacturing a semiconductor element, comprising:
a processing chamber arranged to accommodate at least a portion of a flexible substrate which has a plurality of effective regions arranged therein along a length direction, and which is step-transferred by one effective region each time;
a first electrode and a second electrode which are provided in the processing chamber so as to face each other; and
a mask portion provided between the first electrode and the second electrode, and having an opening so as to expose the effective region when each effective region of the flexible substrate is step-transferred between the first electrode and the second electrode; wherein
plasma processing using plasma generated between the first electrode and the second electrode is performed on each effective region of the flexible substrate through the opening of the mask portion, thereby manufacturing a semiconductor element; and
the processing chamber includes:
a plasma processing portion arranged to perform the plasma processing on an effective region of the flexible substrate which is exposed from the opening of the mask portion;
a first standby portion which is provided on a carry-in side of the plasma processing portion so as to overlap the mask portion, and in which an effective region of the flexible substrate prior to the plasma processing is positioned; and
a second standby portion which is provided on a carry-out side of the plasma processing portion so as to overlap the mask portion, and in which an effective region of the flexible substrate after the plasma process is positioned.

11. The apparatus of claim 10, wherein the processing chamber is configured so as to accommodate at least adjacent three effective regions of the flexible substrate.

12. The apparatus of claim 10, wherein a protruding wall, which is in contact with a region between the effective regions of the flexible substrate to provide isolation from the plasma processing portion, is provided along an inner peripheral end and an outer peripheral end of the mask portion.

13. The apparatus of claim 10, wherein multiple ones of the processing chamber are successively arranged along the length direction of the flexible substrate.

14. The apparatus of claim 10, wherein a carry-in portion arranged to carry the flexible substrate into the processing chamber, and a carry-out portion arranged to carry the flexible substrate out of the processing chamber are provided in the processing chamber, and an opening/closing gate arranged to hold a region located between the effective regions of the flexible substrate to hermetically seal the processing chamber is provided in each of the carry-in portion and the carry-out portion.

15. The apparatus of claim 10, wherein a heater arranged to heat the flexible substrate is provided in the first standby portion.

16. The apparatus of clam 10, wherein the processing chamber is configured so that a deposition process is performed by plasma CVD.

17. A method for manufacturing a semiconductor element, comprising:
a transfer step of step-transferring a flexible substrate, which has a plurality of effective regions arranged along a length direction, by one effective region each time at least in a processing chamber; and
a plasma processing step of performing plasma processing in the processing chamber on each effective region of the flexible substrate step-transferred in the transfer step; wherein
in the plasma processing step, at least adjacent three effective regions of the flexible substrate are accommodated in the processing chamber, and an inner one of the accommodated at least three effective regions is plasma-processed.

18. A semiconductor element manufactured by the method of claim 17.
